(19) United States
(12) Patent Application Publication
(10) Pub. No.: US 2007/0283891 A1
(43) Pub. Date: Dec. 13, 2007

(54) Table for supporting substrate, and vacuum-processing equipment

(76) Inventor: Nobuyuki Okayama, Amagasaki-Shi (JP)

Correspondence Address: Michael A. Makuch;Smith, Gambrell & Russell, Suite 800, 1850 M Street, N.W.,, Washington, DC, 20036, US

(21) Appl. No.: 11/727,407

(22) Filed: Mar. 26, 2007

Related U.S. Application Data
(60) Provisional application No. 60/792,977, filed on Apr. 19, 2006.

(30) Foreign Application Priority Data
Mar. 29, 2006 (JP) 2006-089923

(51) Int. Cl. C23C 16/54; C23F 1/00

(52) U.S. Cl. 118/728; 156/345.51

(57) ABSTRACT

The present invention is a table for supporting a substrate to be processed, comprising a metallic member, and a ceramic plate laminated to the top surface of the metallic member, characterized in that an electrostatic chuck electrode is embedded in the ceramic plate, that a groove for forming a cooling medium passageway is made in at least one of the back surface of the ceramic plate and the top surface of the metallic member, and that the ceramic plate and the metallic member are joined together with an adhesive layer.

### BACKGROUND OF THE INVENTION

1. Field of the Invention

The present invention relates to a table for supporting a substrate to be subjected to vacuum processing such as plasma processing, and to a vacuum-processing unit comprising the table.

2. Background Art

The process of semiconductor device production includes many steps in which a substrate is processed in vacuum, such as the step of depositing a film on a substrate by CVD (chemical vapor deposition), and the step of etching a substrate surface. In a processing unit for use in such vacuum processing, a table 91 for supporting a semiconductor wafer (hereinafter referred to simply as a wafer) W, which also serves as a lower electrode, is positioned in a processing vessel 9, as shown in FIG. 5, for example. Above the table 91 is positioned a gas-supply chamber 92 that also serves as an upper electrode. When radio-frequency voltage for creating plasma is applied to the table 91 by an RF generator 91a, plasma is produced between the table 91 and the gas-supply chamber 92. This plasma activates a process gas introduced into the processing vessel 9 from the gas-supply chamber 92. In an atmosphere of this activated gas, the wafer W placed on the table 91 is processed as predetermined.

The table 91 is composed of a metal-made supporting member 93 (metallic member), an electrostatic chuck 94 placed on top of the supporting member 93, and a focus ring 96 surrounding the electrostatic chuck 94. The structure of the electrostatic chuck 94 is that a chuck electrode 94a in sheet form, made of tungsten or the like, is sandwiched between insulating layers 94b made from a dielectric material such as alumina. When DC voltage (chuck voltage) is applied to the chuck electrode 94a by a DC power supply 95, the insulating layer 94b surface generates Coulomb force, so that the wafer W is electrostatically adsorbed by and retained on the insulating layer 94b. In FIG. 5, reference numeral 97 denotes an exhaust tube through which the gas in the processing vessel 9 is exhausted.

Most of conventional electrostatic chucks have been of thermal-spray-coated type, produced by thermally spraying alumina or the like to form two insulating layers on the top and back surfaces of a chuck electrode in sheet form, made from tungsten or the like.

The electrostatic chuck produced in the above-described manner is disadvantageous in that the insulating layers can crack in a high-temperature processing atmosphere because of the thermal stress caused by the difference in coefficient of thermal expansion between the chuck electrode and the insulating layer. Another problem with the electrostatic chuck of this type is as follows: since the insulating layer formed on the top surface of the chuck electrode by thermal spraying has a rough surface, it separates easily from the chuck electrode, beginning from its protruding portions, to become particles and these particles unfavorably stick to the back surface of a wafer.

In order to avoid the above problems, a ceramic plate made of a material having high resistance to thermal stress, capable of forming a less irregular, flat surface, such as aluminum nitride, has come to be used as the insulating layer 94b. The structure of a table 91 using this ceramic plate as the insulating layer 94b is as shown in FIG. 5, for example. Namely, an electrostatic chuck 94 is composed of a ceramic plate serving as the insulating layer 94b,. and a chuck electrode 94a in sheet form, embedded in the ceramic plate. This electrostatic chuck 94 is joined, with an adhesive layer 98, to a supporting member 93 made of such a material as aluminum, fixed to the bottom of a processing vessel 9. A silicone adhesive resin, for example, is used for the adhesive layer 98.

Further, the above-described table 91 has a cooling medium passageway 93a in the supporting member 93. By letting a cooling medium, adjusted to a predetermined temperature, flow in the cooling medium passageway 93a, it is possible to control the surface temperature of the supporting member 93 to a predetermined standard temperature. Thus, the wafer W whose temperature rises high due to heat entering from the plasma can dissipate the heat, via the electrostatic chuck 94, the adhesive layer 98, and the supporting member 93, to the cooling medium flowing in the cooling medium passageway 93a. The wafer W temperature can thus be controlled to a predetermined processing temperature.

However, the above-described electrostatic chuck 94 of ceramic plate type is disadvantageous in that since the adhesive layer 98 (made from a silicone adhesive resin) with which the electrostatic chuck 94 and the supporting member 93 are joined together has low thermal conductivity, the heat of the wafer W cannot transfer to the supporting member 93 easily. On the other hand, since the surface temperature of the table 91 is determined by the balance of the incoming of heat from the plasma and the outgoing of heat to the cooling medium passageway, it remains unsteady for a certain period of time after the operation of the unit has been started, or after a lot change accompanied by a change of processing temperature has been made, and first several sheets of the wafer W are inevitably processed under unsteady temperature conditions. Therefore, if the heat of the wafer W does not transfer to the cooling medium easily and the above-described incoming and outgoing of heat are not balanced immediately, it requires long time before the surface temperature of the table 91 becomes steady after the initiation of processing of the wafer W. In this case, a large number of sheets of the wafer W are processed under unsteady temperature conditions, which causes a decrease in yield.

A focus ring 96 is put around the adhesive layer 98. There is a narrow gap between the adhesive layer 98 and the focus ring 96, so that the side face of the adhesive layer 98 is exposed to active species in the plasma while the wafer W is processed. The silicone adhesive resin used for forming the adhesive layer 98 is poor in resistance especially to fluorine (F) radial. For this reason, in processing in which fluorine radical is generated, such as etching using a process gas containing fluorine, the fluorine radical corrodes the side face of the silicone adhesive resin layer. The side face of the adhesive layer 98, attacked by the fluorine radical, becomes poor in thermal conductivity. Consequently, the heat that has entered the wafer W from the plasma cannot transfer to the supporting member 93 easily for dissipation via the side face of the adhesive layer 98. Namely, as the adhesive layer 98 corrodes, the temperature of the outer periphery of the wafer W increases, and, as a result, the uniformity in processing, such as the in-plane uniformity in rate of etching, lowers. This makes the life of the electrostatic chuck 94 shorter.

In order to process the wafer W with sheet-to-sheet uniformity, it is necessary to make not only the surface temperature of the table 91 but also the temperature of the focus ring 96 steady as soon as possible immediately after starting the operation of the unit, or after making a lot change.

In order to overcome the above-described shortcomings that the adhesive layer is poor in thermal conductivity and that corrosion of the side face of the adhesive layer makes it difficult to control the wafer temperature, a table having a cooling medium passageway made in a ceramic plate, a component of an electrostatic chuck, has been proposed in Japanese Laid-Open Patent Publication No. 2003-77996 (especially from the 22^{nd} paragraph on page 3 to the 24^{th} paragraph on page 4), for example. More specifically, the ceramic plate described in the above publication is thicker than conventional ones; a groove is made in the back surface of the ceramic plate; and the ceramic plate is put on a supporting member having a smooth top surface and these two are clamped. Together with the top surface of the supporting member, the groove in the back surface of the ceramic plate forms a cooling medium passageway. In such a table, since the ceramic plate on which a wafer will be placed is in direct contact with a cooling medium, the resistance to heat transfer from the wafer to the cooling medium is low. It is therefore possible to shorten the time required for the surface temperature of the table 91 to become steady. Further, since the ceramic plate is fixed to the supporting member by a clamp, the adhesive layer never corrodes.

In the meantime, in order to make the wafer temperature uniform in the wafer plane, it is necessary to make the cooling medium passageway not only in the outer edge portion but also in the center portion of the ceramic plate. On the other hand, since the clamp is generally designed so that it holds the ceramic plate and the supporting member together at the outer edge portion, the force with which the ceramic plate is pressed onto the supporting member is weak at the center portion. Therefore, in the table disclosed in the above-described patent document (Japanese Laid-Open Patent Publication No. 2003-77996), there is the possibility that the cooling medium leaks from a part of the cooling medium passageway, existing in the center portion of the ceramic plate, in which the pressing force is weak as described above, and flows into the adjacent part of the passageway (to form a bypass). In this case, the expected cooling effect cannot be obtained sometimes. Another problem with this table is that since the ceramic plate has increased thickness, the distance between the supporting member and the wafer is longer, and the proportion of the electric power used for the production of plasma to the radio-frequency power applied to the supporting member is therefore lower. This means that power consumption increases.

### SUMMARY OF THE INVENTION

The present invention was accomplished in order to solve the above-described problems in the prior art. An object of the present invention is to provide a table for supporting a substrate to be processed, that is produced by laminating, to the top of a metallic member, a ceramic plate in which an electrostatic chuck electrode is embedded, and that is improved in the cooling efficiency of a cooling medium. Another object of the invention is to provide a vacuum-processing unit comprising the above table.

The present invention is a table for supporting a substrate to be processed, comprising a metallic member, and a ceramic plate laminated to a top surface of the metallic member, wherein an electrostatic chuck electrode is embedded in the ceramic plate, a groove for forming a cooling medium passageway being made in at least one of a back surface of the ceramic plate and the top surface of the metallic member, and the ceramic plate and the metallic member are joined together with an adhesive layer.

According to the present invention, a cooling medium passageway in which a cooling medium for cooling a wafer is allowed to flow is made between the top surface of the metallic member and the back surface of the ceramic plate by which a substrate, such as a wafer, to be processed is electrostatically adsorbed, and the metallic. member and the ceramic plate are joined together with an adhesive layer. Therefore, there can be obtained high cooling efficiency, and the surface temperature of the ceramic plate becomes steady immediately. It is thus possible to process the substrate with sheet-to-sheet uniformity in processing temperature. Furthermore, in the table of the invention, the cooling medium does not leak from the cooling medium passageway, unlike in a conventional table in which a ceramic plate is mechanically fixed to a metallic member by a clamp or the like, so that the expected cooling effect can be surely obtained.

Preferably, the groove is made not in the metallic member but only in the ceramic plate.

Further, it is preferred that the adhesive layer be also formed on a portion of the metallic member surface that faces the groove.

Furthermore, the electrostatic chuck electrode is positioned so that the ceramic plate can also electrostatically adsorb a focus ring put around the substrate to be processed.

Furthermore, an electrode for generating plasma may be placed in the ceramic plate, above the cooling medium passageway. Alternatively, the electrostatic chuck electrode may also serve as an electrode for generating plasma.

The present invention is also a vacuum-processing unit comprising a processing vessel in which a substrate to be processed is placed, a table set forth in claim 1, placed in the processing vessel, a process-gas inlet for introducing a process gas into the processing vessel, and a means of evacuating the processing vessel.

### BRIEF DESCRIPTION OF THE DRAWINGS

In the drawings,

FIG. 1 is a diagrammatical, longitudinal section of a table according to an embodiment of the present invention,

FIG. 2 is a perspective view of the table shown in FIG. 1,

FIG. 3 is a plane view of a ceramic plate, a component of the table shown in FIG. 1,

FIG. 4 is a diagrammatical, longitudinal section of a plasma-processing unit comprising the table shown in FIG. 1, and

FIG. 5 is a diagrammatical, longitudinal section of a plasma-processing unit comprising a conventional table.

### BEST MODE FOR CARRYING OUT THE INVENTION

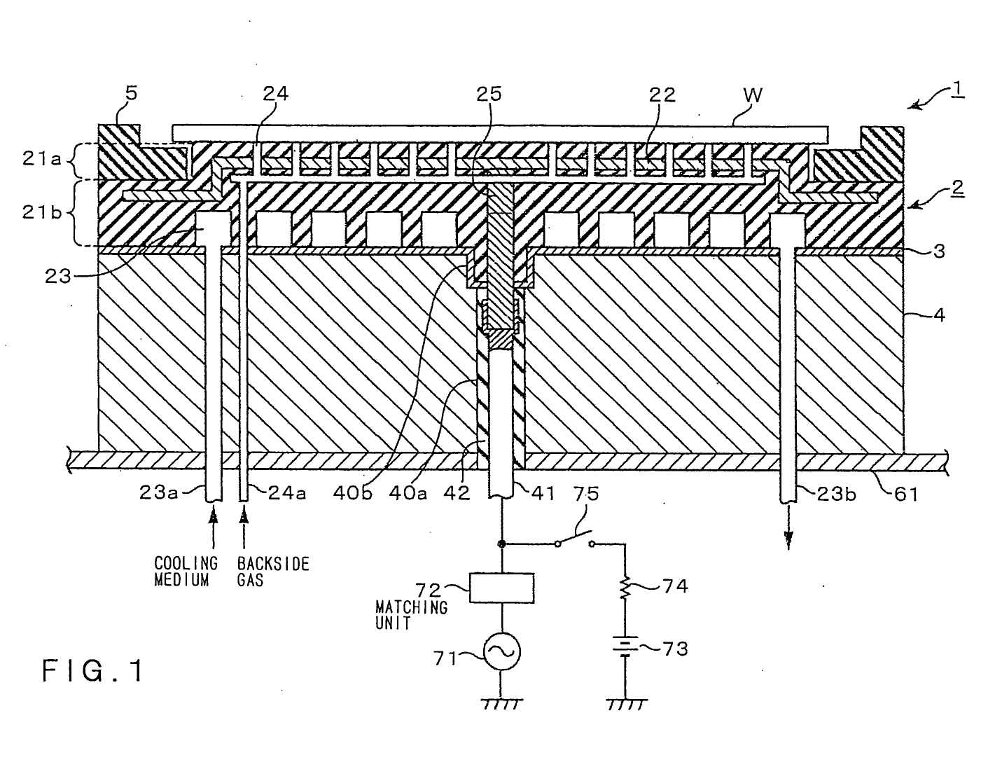

With reference to FIGS. 1 to 3, an embodiment of a table according to the present invention will be described hereinafter. In the following description, a table for use in a vacuum-processing unit in which a wafer, a substrate to be processed, is processed in vacuum, such as a plasma-processing unit in which a wafer is etched by plasma etching, will be taken as example. FIG. 1 is a diagrammatical, longitudinal section of a table 1 according to an embodiment of the present invention.

The table 1 is in the form of a cylinder, for example, and is composed of an electrically conductive supporting member 4 (metallic member) made of aluminum or the like, and a ceramic plate 2 laminated to the top surface of the supporting member 4. The supporting member 4 serves to position the ceramic plate 2 so that a wafer W is held in position in a plasma-processing unit. In the plasma-processing unit, the supporting member 4 is set on the bottom plate of a processing vessel 61 in which the table 1 is incorporated.

The cylindrical supporting member 4 has a through hole 40a made in the vertical direction at around the center. The upper end part 40b of this through hole 40a has a diameter greater than that of the other part of the through hole 40a. A first electrode rod 41 made from an electrically conductive material such as aluminum, inlet in an insulating sleeve 42, is inserted in the through hole 40a. The first electrode rod 41 has, at its upper end, an internal thread part that engages an external thread part at the lower part of a second electrode rod that will be described later.

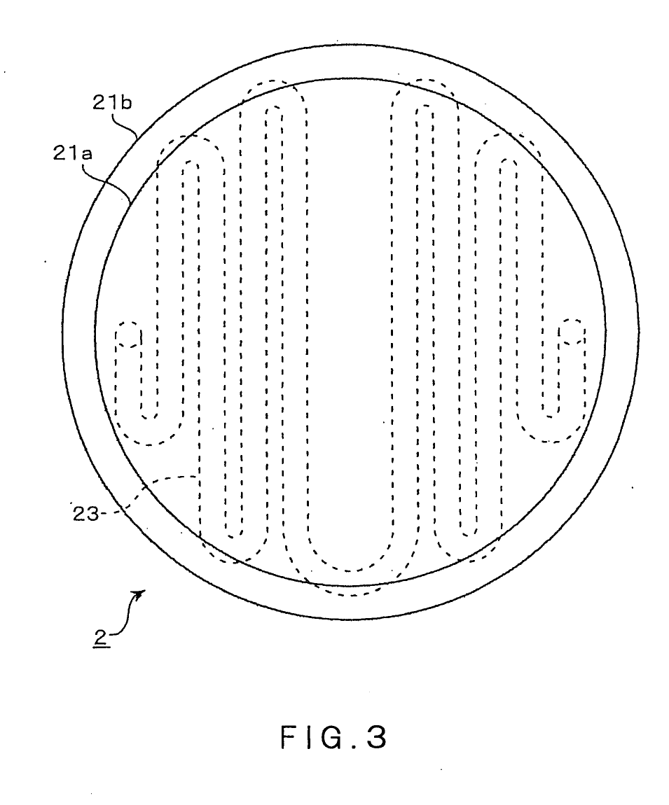

Next, the ceramic plate 2, and an electrode 22 in sheet form, embedded in the ceramic plate 2, will be described below. In this embodiment, the ceramic plate 2 has the function of an electrostatic chuck that retains both a wafer W to be processed and a focus ring 5, which will be described later, by electrostatically adsorbing them, as well as the function of a lower electrode of the plasma-processing unit. The ceramic plate 2 is made of a dielectric material, such as aluminum nitride, having relatively high thermal conductivity as compared to other ceramic materials, and is in the shape of a flat cylinder stepped at the outer edge of its top surface, as shown in FIGS. 1 and 3. In other words, the ceramic plate 2 is composed of a disc-shaped lower plate part 21b having almost the same diameter as that of the supporting member 4, and a disc-shaped upper plate part 21a having a diameter slightly smaller than that of a wafer W, the two parts being superposed concentrically. Further, as shown in FIG. 1, the ceramic plate 2 has, on its back surface at around the center, a protrusion that engages the part 40b of the supporting member 4. Owing to this protrusion, the ceramic plate 2 can be fixed to the supporting member 4 without getting out of position.

The electrode 22 is made of molybdenum or tungsten, for example, and is in sheet form. As shown in FIG. 1, the sheet electrode 22 is embedded in the ceramic plate 2 in the vicinity of its surface so that it covers almost the entire ceramic plate 2 area shown in FIG. 3. The sheet electrode 22 is connected to the upper end of a second electrode rod 25 serving as a conductive path that carries electric power to the sheet electrode 22. The second electrode rod 25 is made of an electrically conductive material such as aluminum and has an external thread part at its lower end. When the second electrode rod 25 and the first electrode rod 41 are engaged, a conductive path running through the whole table 1 is formed. Owing to this conductive path, electric power can be supplied to the sheet electrode 22 by an external power supply.

An RF generator 71 is connected to the first electrode rod 41 via a matching unit 72, so that radio-frequency power can be supplied to the sheet electrode 22. In this embodiment, the RF generator 71 is used to supply bias power for attracting ions present in the plasma. An RF generator for supplying, to the sheet electrode 22, radio-frequency power for creating plasma may further be connected to the first electrode rod 41. In this case, this RF generator is connected to the first electrode rod 41 via a rectifier suited for the RF generator. A DC power supply 73 is also connected to the first electrode rod 41 via a switch 75 and a resistance 74, so that it is also possible to supply DC power to the sheet electrode 22.

On the other hand, the ceramic plate 2 has a winding groove in its back surface, as shown in FIGS. 1 and 3. When the ceramic plate 2 is placed on top of the supporting member 4, the groove in the ceramic plate 2 and the flat top surface of the supporting member 4 form space that will be used as a cooling medium passageway 23. In FIG. 1, reference numeral 23a denotes a cooling-medium supply pipe, and reference numeral 23b, a cooling-medium discharge pipe. A cooling medium, such as Galden (trademark), controlled to a predetermined temperature by a temperature controller, not shown in the figure, is supplied to the cooling-medium passageway 23 from a cooling-medium supply unit, not shown in the figure. A temperature sensor, not shown in the figure, is attached to the ceramic plate 2 in the vicinity of its surface. This sensor continually monitors the surface temperature of the ceramic plate 2. Based on the data from the sensor, the temperature of the cooling medium is controlled by the temperature controller. The surface temperature of the ceramic plate 2 can thus be controlled to a predetermined temperature, for example, a temperature between 10° C. and 60° C.

The ceramic plate 2 and the supporting member 4 are joined together with an adhesive layer 3 consisting of a silicone adhesive resin or the like. If an adhesive resin is applied to the entire top surface of the supporting member 4, not only those portions of the supporting member 4 surface at which the supporting member 4 and the ceramic plate 2 are joined together, but also the other portions of the supporting member 4 surface that constitute the supporting-member 4-side wall of the cooling medium passageway 23 are covered with the adhesive layer 3. As compared with such metals as aluminum, silicone adhesive resins have low thermal conductivity. Therefore, the adhesive layer made from a silicone adhesive resin also functions as a heat insulator that prevents the cooling medium flowing in the cooling medium passageway 23 from absorbing the heat of the supporting member 4 that is not the object of temperature control. Namely, the adhesive layer 3 acts to join and fix the ceramic plate 2 to the supporting member 4, and, at the same time, serves as a heat insulator for insulating the supporting member 4.

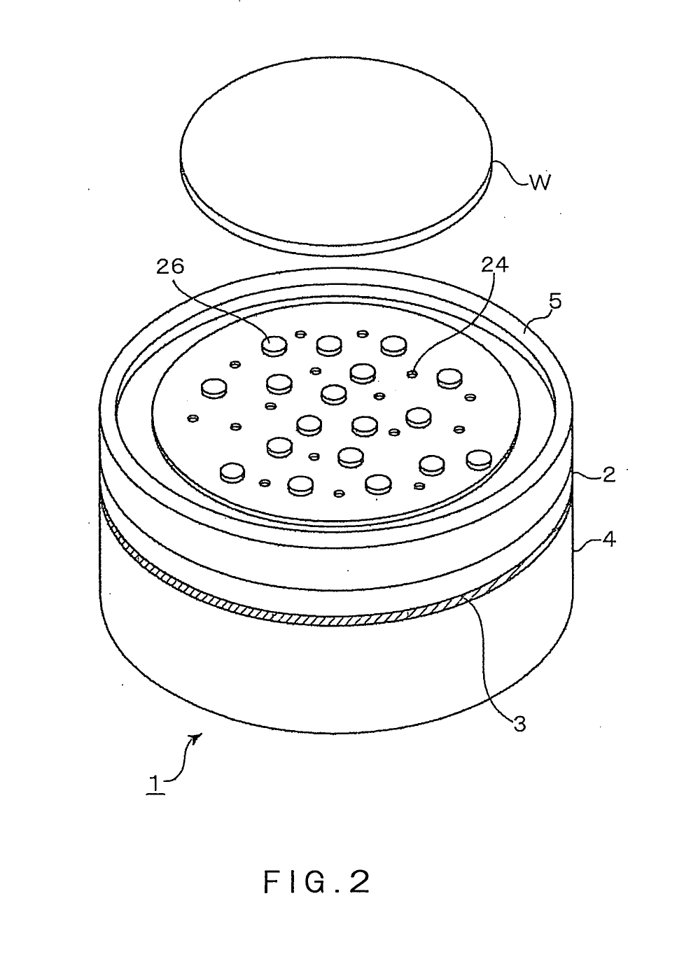

In FIGS. 1 and 2, reference numeral 24 denotes holes from which a heat-conductive backside gas, such as helium (He) gas, is ejected in order to promote heat transfer between the top surface of the ceramic plate 2 and the back surface of the wafer W. Reference numeral 24a denotes a pipe for supplying the backside gas.

On the top surface of the upper plate part 21a, there are a large number of thin-disc-shaped protrusions called dots 26. These dots 26 decrease the wafer W/ceramic plate 2 contact area and secure the contact of the wafer W and the ceramic plate 2, thereby ensuring electrostatic adsorption of the wafer W by the ceramic plate 2. The dots 26 also act to prevent the particles from sticking to the back surface of the wafer W. Further, since a gap is made between the back surface of the wafer W and the top surface of the ceramic plate 2, the backside gas ejected from the holes 24 can flow easily, which leads to an improvement in the efficiency of heat transfer between the wafer W and the ceramic plate 2. The dots 26 are omitted from the figures other than FIG. 2.

In FIGS. 1 and 2, reference numeral 5 denotes a focus ring that acts to control the state of the plasma present in the area outside the outer edge of the wafer W in the course of plasma processing of the wafer W. In this embodiment, the focus ring 5 is put on the ceramic plate 2 so that the plasma extends beyond the wafer W to improve the uniformity in rate of etching in the wafer plane. The focus ring 5 in this embodiment is made of a conductive material such as silicone and is in the shape of an annular ring with a step cut in its inner rim, as shown in FIG. 1.

The focus ring 5 is put on top of the lower plate part 21b of the ceramic plate 2, that is, on the outer-edge-side annular surface of the ceramic plate 2 shown in FIG. 3. When the focus ring 5 is put on the ceramic plate 2 in this manner, its inside step surrounds the outer periphery of the upper plate part 21a of the ceramic plate 2 with a slight gap, as shown in FIGS. 1 and 2. The top surface of the step cut in the inner rim of the focus ring 5 is slightly lower in height than the top surfaces of the dots 26 on which a wafer W is placed. Moreover, the diameter of the upper plate part 21a is slightly smaller than that of the wafer W. Therefore, the outer edge portion of the wafer W placed on the table 1 is in the state of floating above the inside step of the focus ring 5, with a slight gap.

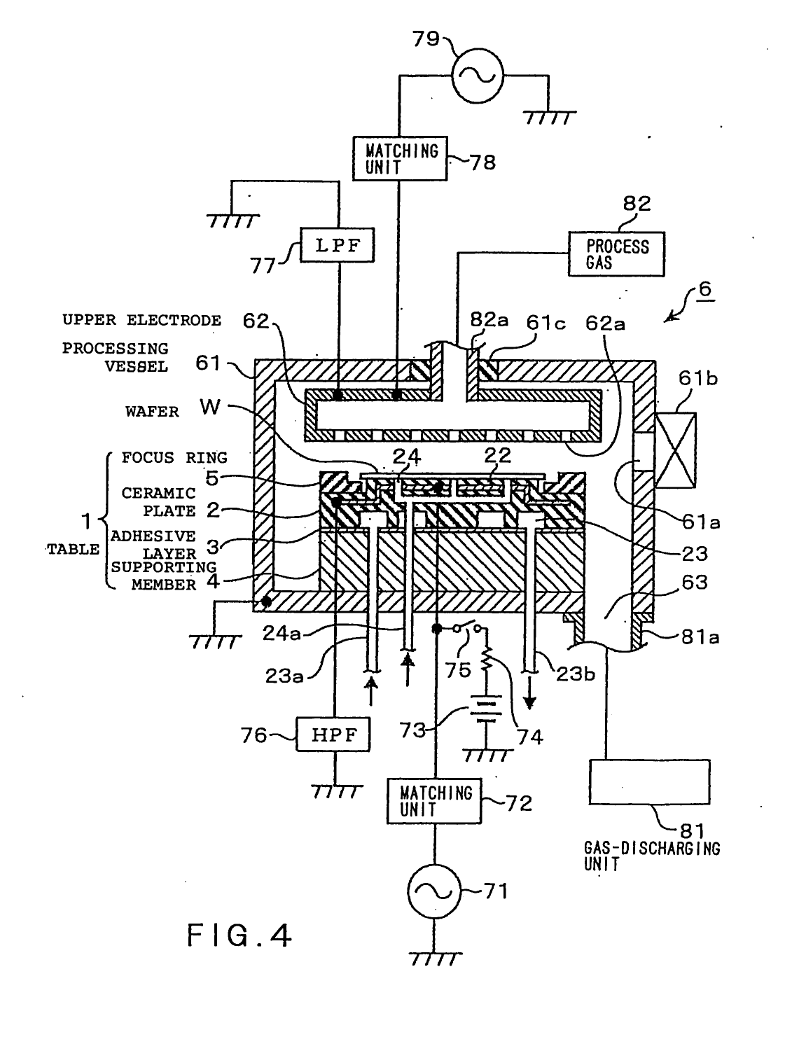

Next, a plasma-processing unit 6 comprising the table 1 of this embodiment will be described hereinafter with reference to FIG. 4. The plasma-processing unit 6 shown in FIG. 4 comprises a processing vessel 61 composed of a closed vacuum chamber, a table 1 according to this embodiment, placed in the processing vessel 61 and fixed to its bottom plate at the center, and an upper electrode 62 placed above and in parallel with the table 1. The first electrode rod 41 and the second electrode rod 25 that constitute the conductive path in the table 1 are omitted from this figure.

The processing vessel 61 is electrically grounded. A gas-discharge port 63 in the bottom plate of the processing vessel 61 is connected, via a gas-discharge pipe 81a, to a gas-discharging unit 81 composed of a vacuum pump or the like. The processing vessel 61 has, in its sidewall, an opening 61a through which a wafer W is carried into and out of the processing vessel 61. This opening 61a can be opened or closed by switching a gate valve 61b.

The sheet electrode 22 embedded in the ceramic plate 2 in the table 1 is grounded via a high-pass filter (HPF) 76. The RF generator 71 (first RF generator) connected to the sheet electrode 22 supplies radio-frequency power of 13.56 MHz, for example, to the sheet electrode 22.

An upper electrode 62 is hollow and has, in its bottom surface, a large number of process-gas supply holes 62a for supplying a process gas into the processing vessel 61, arranged uniformly, for example. Namely, the upper electrode 62 serves as a gas-shower head. Further, a process-gas supply tube 82a is inserted into a hole made in the top surface of the processing vessel 61 at the center, the inner wall of the hole being covered with an insulating member 61c, and is connected to the top surface of the upper electrode 62 at the center. The upstream end of this process-gas supply tube 82a is connected to a process-gas supply unit 82. The process-gas flow rate and the supply of the process gas are controlled by a valve and a gas flow rate controller, which are not shown in the figure.

The upper electrode 62 is grounded via a low-pass filter (LPF) 77. To this upper electrode 62, an RF generator 79 that generates a radio-frequency of 60 MHz, for example, higher than the frequency generated by the first RF generator 71 is connected as a second RF generator via a matching unit 78. The radio-frequency power supplied by the second RF generator 79 is for making the process gas into plasma, and the radio-frequency power supplied by the first RF generator 71, for applying bias power to the wafer W so that its surface attracts ions present in the plasma. The RF generators 79, 71 are connected to controllers, not shown in the figure, and the supply of electric power to the upper electrode 62 and that to the sheet electrode 22 are controlled according to the signals from these controllers.

The action of this embodiment will now be described. First, the gate valve 61b is opened, and by a carrier arm, not shown in the figure, a wafer W is carried into the processing vessel 61 through the opening 61a and is placed on top of the ceramic plate 2 in the processing vessel 61. After withdrawing the carrier arm from the processing vessel 61 and closing the gate valve 61b, the gas in the processing vessel 61 is evacuated from the gas-discharge port 63 to produce a vacuum. At this time, DC voltage is applied by the DC power supply 73 to the sheet electrode 22 serving as an electrostatic chuck electrode. Owing to the Coulomb force generated in this manner, the wafer W is electrostatically adsorbed by the surface of the ceramic plate 2. The focus-ring 5-supporting portion of the ceramic plate 2 surface also generates Coulomb force when DC voltage is applied to the sheet electrode 22, so that the ceramic plate 2 also electrostatically adsorbs the back surface of the focus ring 5.

Thereafter, a cooling medium is allowed to flow in the cooling medium passageway 23, and, at the same time, a backside gas is ejected from the holes 24. Subsequently, a process gas, such as C₄ F₈, is showered on the wafer W, and radio-frequency voltage is applied to the upper electrode 62 by the RF generator 79, thereby producing plasma. A film, such as a silicone oxide film, on the wafer W surface is then etched by applying radio-frequency voltage to the sheet electrode 22 serving as a lower electrode by the RF generator 71.

Since the sheet electrode 22, a radio-frequency electrode, is embedded in the ceramic plate 2 in the vicinity of its surface, power loss caused by the ceramic plate 2 that is made thick in order to make the cooling medium passageway 23 in it is small. Further, since the radio-frequency voltage applied to the sheet electrode 22 creates an electric field in the vicinity of the ceramic plate 2 surface, it is expected that the particles present in the processing vessel 61 will be repelled and scarcely stick to the wafer W.

When the wafer W is exposed to the plasma, its temperature increases. However, since the surface of the ceramic plate 2 is controlled to a standard temperature of 60° C., for example, by the cooling medium flowing in the cooling medium passageway 23, the heat of the wafer W transfers to the cooling medium flowing in the cooling medium passageway 23, via the ceramic plate 2 without passing through the members other than the thin sheet electrode 22. The temperature of the wafer W can thus be controlled to a predetermined processing temperature.

The supporting-member 4-side wall of the cooling medium passageway 23 is covered with the adhesive layer 3 with which the supporting member 4 and the ceramic plate 2 are joined together, so that the heat of the supporting member 4 does not transfer to the cooling medium easily. Therefore, the cooling medium flowing in the cooling medium passageway 23 can efficiently absorb the heat that has transferred mainly from the wafer W.

Further, when the ceramic plate 2 electrostatically adsorbs the back surface of the focus ring 5, the ceramic plate 2/focus ring 5 contact area increases and the gap between the two decreases, so that the heat of the focus ring 5 easily transfers to the ceramic plate 2. Consequently, the temperature of the focus ring 5 does not rise high.

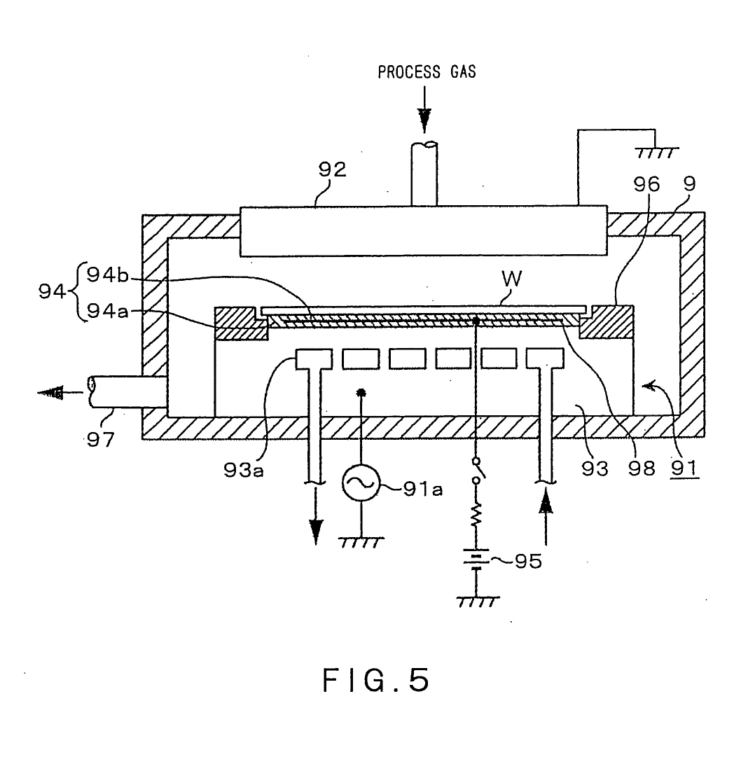

As is clear from a comparison between FIGS. 1 and 5, since the ceramic plate 2 according to this embodiment is made thicker than ever in order to make, in it, a groove for the cooling medium passageway 23, the position of the cooling medium passageway 23/supporting member 4 joint area is lower than ever before. Therefore, the plasma does not reach the joint area easily, and the side face of the adhesive layer 3 is not corroded easily by radicals, such as fluorine radical, generated from the process gas such as C₄F₈ gas. Even if part of the radicals, such as fluorine radical, reaches the adhesive layer 3 to attack its side face, since the distance between the adhesive layer 3 and the wafer W is greater than ever, it is considered that the control of the wafer W temperature is scarcely affected by the corrosion of the side face of the adhesive layer 3.

The wafer W etched through the above-described procedure is carried out of the processing vessel 61 in the order reverse to that in which it was carried into the processing vessel 61.

In this embodiment, the table 1 is incorporated in the plasma-processing unit 6. However, vacuum-processing equipment in which the table 1 of the present invention can be incorporated is not limited to plasma-processing units. The table 1 according to the present invention can also be used in a CVD system or the like in which a film is deposited on a wafer or the like.

Further, the present invention is applicable not only to a vacuum-processing unit of the above-described type in which the first and second RF generators are connected to the lower and upper electrodes, respectively, but also to a vacuum-processing unit of other type in which both first and second RF generators are connected to a sheet electrode 22 (lower electrode), for example.

Furthermore, in the above description of this embodiment, the sheet electrode 22 serves as a chuck electrode and also as a lower electrode (radio-frequency electrode) that takes part in plasma processing. Instead of this sheet electrode 22, a chuck electrode and a lower electrode may be made separately and embedded in the ceramic plate 2. Moreover, the sheet electrode 22 of this embodiment serves as a chuck electrode for causing the ceramic plate 2 to electrostatically adsorb the. wafer W and as a chuck electrode for causing the ceramic plate 2 to electrostatically adsorb the focus ring 5. Two chuck electrodes of these types may also be made separately and embedded in the ceramic plate 2.

According to the table 1 of this embodiment, a cooling medium passageway 23 in which a cooling medium for cooling a wafer W is allowed to flow is formed between the back surface of the ceramic plate 2 that electrostatically adsorbs a wafer W, a substrate to be processed, and the top surface of the supporting member 4, and these two members 2, 4 are joined together with the adhesive layer. Therefore, there can be obtained high cooling efficiency, and the surface temperature of the ceramic plate 2 becomes steady promptly. It is thus possible to attain wafer-to-wafer uniformity in processing temperature. Further, unlike a conventional table in which a ceramic plate 2 is fixed to a supporting member 4 mechanically by a clamp or the like, the cooling medium never leaks from the cooling medium passageway 23, so that the expected cooling effect can be surely obtained.

Furthermore, since the supporting-member 4-side wall of the cooling medium passageway 23 is covered with the adhesive layer 3, heat does not transfer easily between the supporting member 4 and the cooling medium because of the heat insulating effect of the silicone adhesive resin used for forming the adhesive layer 3, which brings about a further improvement in wafer W cooling efficiency. However, the adhesive layer 3 may not be formed on those portions of the supporting member 4 that constitute the supporting-member 4-side-wall of the cooling medium passageway 23, but formed only on those portions of the supporting member 4 that constitute the ceramic plate 2/supporting member 4 joint area.

In this embodiment, the groove for the cooling medium passageway 23 is made only in the ceramic plate 2. However, the groove may also be made in both the ceramic plate 2 and the supporting member 4, or only in the supporting member 4. In these cases, if a layer of an adhesive resin or the like (adhesive layer) is present not only on the ceramic plate 2/supporting member 4 joint area, but also on the wall of the cooling medium passageway, improved wafer W cooling efficiency can be obtained due to the heat insulating effect of the adhesive resin or the like, as mentioned already.

1. A table for supporting a substrate to be processed, comprising:
a metallic member, and
a ceramic plate laminated to a top surface of the metallic member,
wherein
an electrostatic chuck electrode is embedded in the ceramic plate,
a groove for forming a cooling medium passageway is made in at least one of a back surface of the ceramic plate and the top surface of the metallic member, and
the ceramic plate and the metallic member are joined together with an adhesive layer.

2. The table according to claim 1, wherein
the groove is made not in the metallic member but only in the ceramic plate.

3. The table according to claim 1, wherein
the adhesive layer is also formed on a portion of the metallic member surface that faces the groove.

4. The table according to claim 1, wherein
the electrostatic chuck electrode is positioned so that the ceramic plate can also electrostatically adsorb a focus ring put around the substrate to be processed.

5. The table according to claim 1, wherein
an electrode for generating plasma is placed in the ceramic plate, above the cooling medium passageway.

6. The table according to claim 5, wherein
the electrostatic chuck electrode also serves as an electrode for generating plasma.

7. A vacuum-processing unit comprising:
a processing vessel in which a substrate to be processed is placed,
a table set forth in claim 1, placed in the processing vessel,
a process-gas inlet for introducing a process gas into the processing vessel, and
a gas-discharging unit that evacuates the processing vessel.
